(19) United States
(12) Patent Application Publication
(10) Pub. No.: US 2026/0223726 A1
(43) Pub. Date: Jul. 30, 2026

(54) METHOD FOR MANUFACTURING A CHIP PACKAGE, CHIP PACKAGE, WAFER STRUCTURE, AND METHOD FOR PROCESSING A CHIP PACKAGE COMPONENT

(71) Applicant: Infineon Technologies AG, Neubiberg (DE)

(72) Inventors: Maximilian SIMMANN, Sinzing (DE); Harry SAX, Straubing (DE)

(73) Assignee: Infineon Technologies AG, Neubiberg (DE)

(21) Appl. No.: 19/454,711

(22) Filed: Jan. 21, 2026

(30) Foreign Application Priority Data
Jan. 29, 2025 (DE) 10 2025 103 261.0

(51) Int. Cl. H10W 74/43; C23C 16/40; C23C 16/56; H10W 74/01

(52) U.S. Cl. CPC H10W 74/43; H10W 74/01; C23C 16/403; C23C 16/405; C23C 16/56

(57) ABSTRACT

A chip package and method for manufacturing a chip package is provided. In one example, the method includes forming a metal oxide layer on a chip structure and applying a saline solution to the metal oxide layer to form a layered double hydroxide (LDH).

### CROSS-REFERENCE TO RELATED APPLICATION

This Utility patent application claims priority to German Patent Application No. 10 2025 103 261.0 filed Jan. 29, 2025, which is incorporated herein by reference.

### TECHNICAL FIELD

Various embodiments relate generally to a method for manufacturing a chip package, to a chip package, to a wafer structure, and to a method for processing a chip package component.

### BACKGROUND

Chip technologies are often prone to corrosion and ion driven failures during harsh stress test conditions. These ions may either originate from the environment, or from the epoxy molding compound (EMC) that is used to encapsulate the chip and protect it from the environment and form contaminants in the EMC that may diffuse towards the chip and/or interconnects of the package assembly and may lead to corrosion and charge accumulation within the chip or the interconnects. The charge accumulation could damage or alter the behavior of the chip or package performance and eventually lead to device failure. Some examples are Cu/Al interconnect corrosion, Ag migration, High Temperature Reverse Bias (HTRB) drift behavior and CI-induced corrosion.

### SUMMARY

A method for manufacturing a chip package is provided. The method includes forming a metal oxide layer on a chip structure and applying a saline solution to the metal oxide layer to form a layered double hydroxide (LDH).

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 schematically illustrates a method of forming a chip package in accordance with various embodiments;

FIG. 2 schematically illustrates a method of forming a chip package in accordance with various embodiments;

FIG. 3 compares schematical illustrations of a method of forming a chip package in accordance with various embodiments and of a method of forming a chip package according to a prior art;

FIG. 4 compares schematical illustrations of a method of forming a chip package in accordance with various embodiments and of a method of forming a chip package according to a prior art;

FIG. 5 schematically illustrates a chip package in accordance with various embodiments;

FIG. 6A schematically illustrates a wafer- or chip structure in accordance with various embodiments;

FIG. 6B schematically illustrates a chip package component in accordance with various embodiments;

FIG. 7A shows scanning electron microscope (SEM) images of substrates roughened with a layered double hydroxide (LDH) in accordance with various embodiments, and FIG. 7B shows cross-sectional images of some of the substrates of FIG. 7A;

FIG. 8 shows a scanning electron microscope (SEM) image of a cross section of a silicon substrate roughened with a layered double hydroxide (LDH) in accordance with various embodiments (top) and scanning electron microscope (SEM) images combined with Energy Dispersive X-ray Spectroscopy (EDX) below;

FIG. 9 shows a comparison of ellipsometry measurements on small Si-pieces after hydrothermal treatment in pure DI water (left, prior art) and 0.5 M Zn(NO₃)₂ solution (right, in accordance with various embodiments) at 90° C. for different times;

FIG. 10 shows a flow diagram of a method for manufacturing a chip package in accordance with various embodiments;

FIG. 11 shows a flow diagram of a method for manufacturing a chip package component in accordance with various embodiments; and

FIG. 12 shows a flow diagram of a method for manufacturing a chip package component in accordance with various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

The above described corrosion-related phenomena could be avoided by using a surface passivation after wirebonding and before molding to protect the whole assembly. Therefore, the surface passivation should prevent diffusion of ions, moisture, and molecules through the passivation.

The surface passivation may also be configured to show good adhesion to both the substrate (chip, imide, leadframe) and the molding compound to avoid delamination and further contamination from the environment.

Some mechanical adhesion promoters are presently used.

For example, Cr-A2 and V-A2 are used in the prior art as adhesion promoter in packages to improve the adhesion to the molding compound. However, this adhesion promoter can only be formed on conductive parts of an assembly and are therefore not suitable for protecting the non-conductive parts (e.g. imide on chip).

Another example is the recently developed Rough-Al₂O₃-Adhesion Promoter (DE 10 2018 118 544 A1, U.S. Pat. No. 11,735,534 B2). For forming the Rough-Al₂O₃-Adhesion Promoter layer, nanometric scale Al₂O₃ is deposited uniformly on the assembly by atomic layer deposition (ALD). Afterwards, the Al₂O₃ is roughened by hydrothermal treatment to form a dendritic adhesion promoter. The formed ALD adhesion promoter has a high porosity and a low thickness of dense Al₂O₃ on a substrate that may be prone to ion and moisture diffusion through the ALD layer. Also, Al₂O₃ is weak against moisture and dissolves in acid and alkaline environment, such that a long-term stability of the layer may be questioned.

Furthermore, it is known that the dendritic structure of the rough ALD adhesion promoter leads to improvement in HAST (Highly Accelerated Stress Test) and HTRB (High Temperature Reverse Bias) performance, whereas a dense Al₂O₃ ALD layer does not yield such improvement. Therefore, it is hypothesized that the dendritic AlOOH structure acts as ion trapping, charge-shielding or reaction layer to prevent ion diffusion into the chip technology. As the AlOOH dendrites are prone to moisture and weak against acidic and alkaline environment, the dendrites may degrade over time.

In various embodiments, a conversion of a thin metal oxide layer by hydrothermal treatment with a salt solution to form a layered double hydroxide, which acts as corrosion protection and adhesion promoter, is provided.

In various embodiments, a conversion of the Al₂O₃-ALD layer to a thicker layered double hydroxide (LDH, general formula: [M(II)₁₋ₓM(III)x(OH—)2]x+ [(Xn-)x/n·yH2O]x—) structure (e.g. ZnAl-LDH or MgAl-LDH) is used.

These layered double hydroxides are known in literature for their corrosion protection properties and their ability to catch ions. Also, layered double hydroxides typically grow as dendrites or thin platelets which makes them suitable to act as mechanical adhesion promoters like A2 and Rough-Al₂O₃.

In various embodiments, a uniform layer deposition of Atomic Layer Deposition (ALD) with an ion catching ability of the LDH structures is provided. Hence, a similar concept as the dendritic Al₂O₃ Adhesion Promoter is employed, but with improved properties.

An advantage of these LDHs is their versatility. The LDH may be tailored according to their needed functionality. For example, different inhibitors, hydrophobic agents, and ions (molybdate, vanadate) may be used to increase their protective properties and modify the crystallization behavior to enhance adhesion. The influence of additives in salt solution on LDH crystallization are already known from literature and can therefore be optimized for usage as adhesion promoter. Also, LDH crystallite structure typically grows perpendicular to the surface similar to the dendritic Al₂O₃ ALD structure. Also, various additives can be incorporated into the layer to create a “self-healing” corrosion protection layer which could drastically increase reliability. Thus, a multifunctional passivation layer may in various embodiments be formed with a rough layer on top that may act as adhesion promoter with tunable properties. Examples include acidity and alkalinity, thermal stability, corrosion protection, crystallization formation: size, shape, and an orientation of the crystals: adhesion properties, adsorption of dyes and ions, a catalyst to induce wanted surface reactions, hydrophobicity, and anion exchange

In various embodiments, a formation of the LDH may be realized by ALD of a seed layer (e.g. Al₂O₃ or ZnO) and subsequent hydrothermal treatment of the seed layer. For the hydrothermal treatment, specific salt solutions may be used, e.g. Zn(NO₃)₂ solution to form a ZnAl-LDH.

This process allows to vary ingredients, e. g., the salts, pH and additives (e.g. inhibitors such as silanes, BTA, MoO42-, V2O74-) in the salt solution to form different LDH layers with different properties.

Alternatively or additionally, the ALD layer may be changed to modify the LDH formation process and to combine different properties.

In various embodiments, a manufacturing a chip package is provided. The method includes forming a metal oxide layer on a chip structure and applying a saline solution to the metal oxide layer to form a layered double hydroxide (LDH).

In various embodiments, a roughened AlOOH dendrite structure may be formed in-situ within an ALD chamber from an ALD layer. The in-situ-treatment may for example include a hydrothermal treatment using hot steam/vapor that is introduced into the processing chamber. In various embodiments, a subsequent second ALD deposition may be performed after the in-situ roughening. As an alternative to the in-situ roughening, the roughened AlOOH dendrite structure may be formed (e. g., by hot water dipping) outside the ALD chamber and then be introduced into the chamber for the second ALD deposition.

In various embodiments, a method for processing a chip package component is provided. The method may include hydrothermally treating an aluminum oxide layer arranged on a surface of the chip package component to form a roughened AlOOH-layer, and depositing an ALD layer over the roughened AlOOH-layer.

In various embodiments, a method for processing a chip package component is provided. The method may include arranging the chip package component inside an ALD chamber, forming an ALD aluminum oxide layer over the chip package component, and hydrothermally treating the aluminum oxide layer inside the ALD layer to form a roughened AlOOH-layer.

ALD deposition and LDH formation may in various embodiments be performed as part of a method for manufacturing a chip package after a wirebonding assembly before molding at package level in backend processing to protect the whole assembly (e. g., the chip, a carrier on which the chip is mounted, e. g., a leadframe, a bonding wire, a clip, etc., and in particular interfaces between said components and/or between the components and a mold material of the chip package) from ions and contaminants and environmental influences. Here, the crystallites may be grown perpendicular to the leadframe/substrate and may provide adhesion to the (e. g., epoxy) molding compound.

However, the implementation may be introduced at any step during the packaging process where a passivation or adhesion to a subsequent layer is needed.

Furthermore, the method of various embodiments may be used on any package or chip technology where additional adhesion or passivation is needed.

ALD deposition and LDH formation may in various embodiments be performed before an imide passivation on wafer level to enhance the adhesion of a chip passivation to the imide layer.

Another potential application is the ALD deposition and LDH formation before imide passivation on wafer level to enhance the adhesion of the chip passivation to the imide layer.

Another potential application is to employ this methodology to form the LDH structure directly on an aluminum (Al) leadframe. As there is always native oxide on Aluminum, the Al₂O₃ on the surface can then be used to form the LDH structure as described above. Also, the Al₂O₃ density and thickness can be modified by anodic oxidation process and then be conversed to LDH layer. This methodology is already known from an aluminum eloxation process and corrosion protection. However, in various embodiments, the layer may be used as an adhesion promoter similar to Cr-A2 and V-A2 layers.

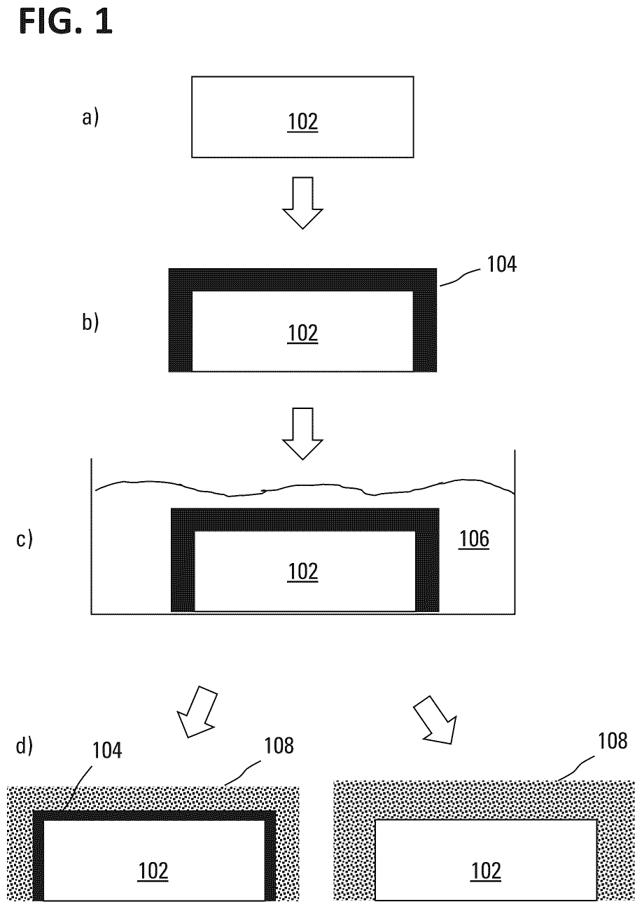

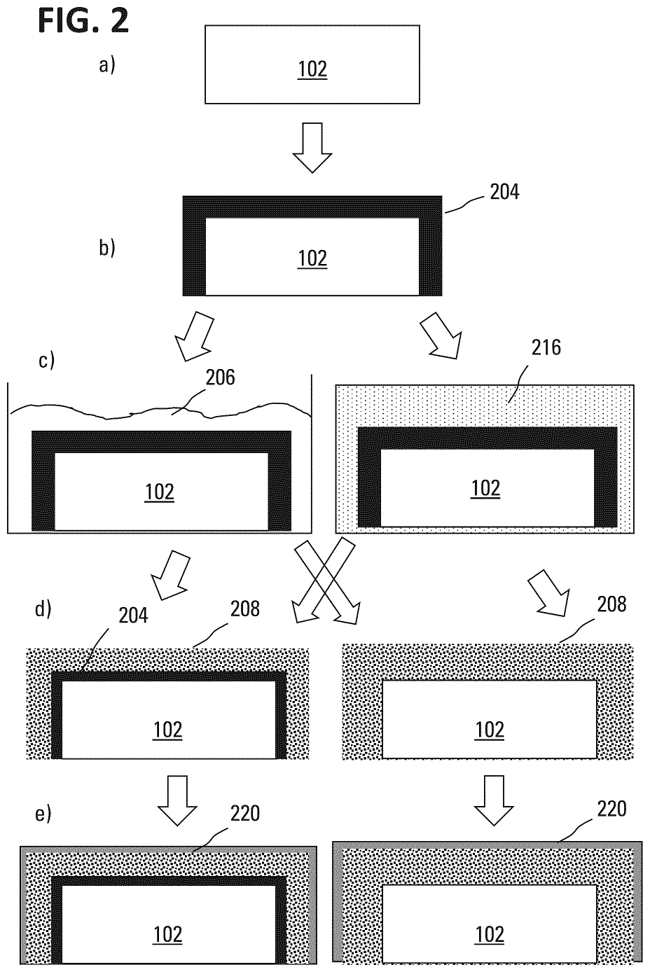

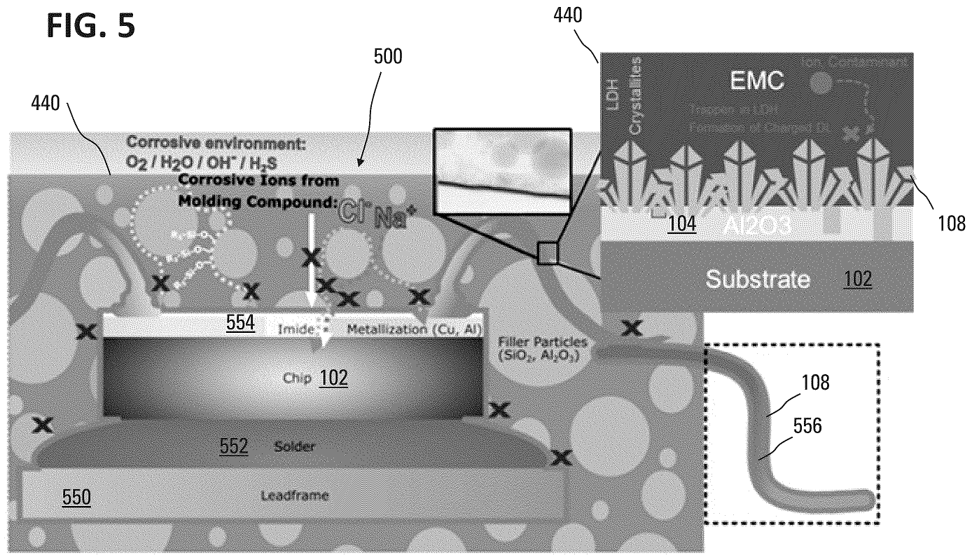

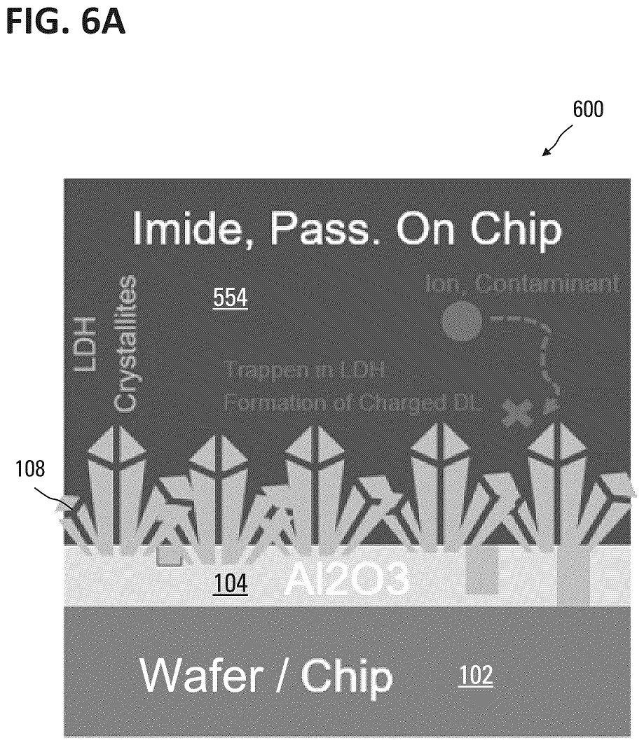

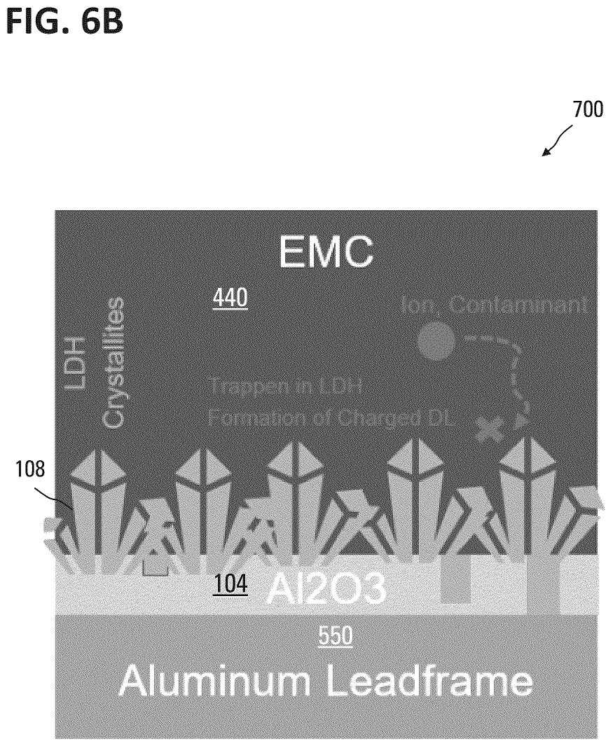

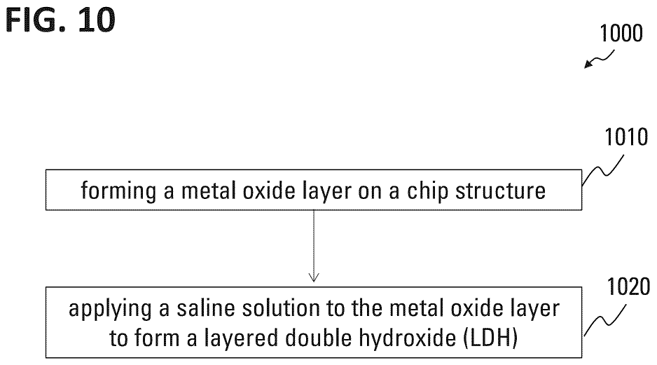

FIG. 1 schematically illustrates a method of forming a chip package 500 in accordance with various embodiments, and FIGS. 5 and 6A schematically illustrate chip packages 500 formed in accordance with various embodiments, for example by the method of FIG. 1, and FIG. 2 schematically illustrates the method of forming a chip package in accordance with various embodiments. FIG. 10 shows a flow diagram of a method for manufacturing a chip package in accordance with various embodiments.

The method includes forming a metal oxide layer 104 on a chip structure 102 (in 1010 and going from panel a) to panel b) in FIG. 2) and applying a saline solution 106 to the metal oxide layer 104 to form a layered double hydroxide (LDH) 108 (1020 and panel c) in FIG. 2). The resulting chip structure 102 with the LDH 108 is shown in panel d) of FIG. 2.

The metal oxide layer 104 may include, essentially consists of or consist of at least one metal oxide of a group of metal oxides. The group may include or consist of: aluminum oxide, zinc oxide, hafnium oxide, manganese oxide, calcium oxide, and iron oxide.

The saline solution 106 may include at least one salt, for example any of the following: Zn(NO₃)₂, Zn(SO₄), Mg(SO₄), Ca(SO₄), and Ca(NO₃)₂.

The saline solution 106 may further include at least one additive, for example at least one of the following: hexamethylentetramine, NaOH, HNO3, and amines.

The saline solution 106 may further include at least one further additive, for example at least one of the following: silanes, triazoles, benzotriazole (BTA), MoOx, VxOy, MnOx, anti-tarnish, and hydrophobic agents.

The following table gives an overview of possible materials that may be selected and combined with each other:

| | Metal for salt | Anion for salt | |
|---|---|---|---|
| Substrate Material | solution | solution | Additives |
| Al₂O₃, AlOOH, | Al³⁺ | (NO₃)⁻; (NO₂)²⁻ | CrO⁴⁻ |
| Al(OH₃) | | | |
| ZnO | Zn²⁺ | (SO₄)²⁻ | MnO⁴⁻ |
| MgO | Mg²⁺ | CrO⁴⁻ | V₂O₇⁴ |
| CaO | Ca²⁺ | MnO⁴⁻ | MoO₄²⁻ |
| FeOx | Fe^{2+/3+} | V₂O₇⁴ | silanes |
| | Mn²⁺ | MoO₄²⁻ | triazoles |
| | Co²⁺ | (CO₃)²⁻ | BTA |
| | Ni²⁺ | Cl⁻ | hydrophobic |
| | | | agents |
| | Cu²⁺ | Br⁻ | anti-tarnish |
| | | | agents |
| | Cr³⁺ | SeO₄²⁻ | |
| | Li⁺ | OH⁻ | |
| | Na⁺ | S²⁻ | |

The forming the chip package 500 may further include forming an encapsulation layer 440 on the layered double hydroxide 108. The encapsulation process and encapsulation material may be similar or identical to those already known in the art.

More specifically, the forming the encapsulation layer may, in various embodiments, include encapsulating the chip 102, and optionally other components of the chip package, in an (e. g., epoxy) molding compound 440.

In various embodiments, the applying a saline solution 106 may include or consists of at least one of a group of techniques, the group consisting of: hydrothermal treatment, a sol-gel method, a coprecipitation method, a template method, a urea hydrolysis method, electrodeposition, spin coating, steaming coating, and anion exchange, which may be essentially known methods for applying a saline solution 106.

In various embodiments, the forming the layered double hydroxide 108 may completely consume the metal oxide layer 104. In other words, process parameters like ALD layer thickness, temperature, duration, conversion method, and/or others that may have an impact on how much of the metal oxide layer 104 reacts with the saline solution to form the LDH layer 108, may be controlled in such a way that the metal oxide layer 104 is completely converted to the LDH 108.

In various embodiments, the forming the layered double hydroxide 108 may consume the metal oxide layer only partially, with a fraction of the thickness of the metal oxide layer 104 remaining between the layered double hydroxide 108 and the chip structure 102, e. g., the chip 102 or a different suitable substrate or carrier, on which the metal oxide layer 104 is arranged, e. g., a wafer, a leadframe, a clip, or the like. In that case, process parameters like ALD layer thickness, temperature, duration, conversion method, and/or others that may have an impact on how much of the metal oxide layer 104 reacts with the saline solution to form the LDH layer 108, may be controlled in such a way that the metal oxide layer 104 is completely converted to the LDH 108.

In various embodiments, for example in a case where the chip structure is a wafer 102, the method may further include forming an imide layer 660 over the layered double hydroxide 108. A schematic illustration of a corresponding embodiment, e. g., a wafer arrangement 600 with an imide passivation 660 over the wafer 102 and a combination of aluminum oxide 104 and a LDH layer 104 as an adhesion promoter between the aluminum oxide 104 and the imide 440, is shown in FIG. 6A.

In various embodiments, another metal oxide layer 104 may be arranged over, e. g. directly or indirectly on, the imide passivation layer 660, to form an adhesion promotion layer between the imide layer 660 and the encapsulation layer 440.

The layered double hydroxide 108, and optionally the imide layer 660, may cover at least one side of the wafer or essentially cover at least one side (e. g., the top side) of the wafer 102. In various embodiments, other sides of the wafer 102, for example its backside and/or one or more of the side surface(s) connecting the front side and the back side, may be covered by the LDH 108.

Due to the known properties of ALD layers like the metal oxide layer 104, in particular that it conforms to surfaces it is formed on, the LDH layer 108 formed by conversion of the metal oxide layer 104 also conforms to surfaces of the chip structure 102.

In various embodiments, the wafer 102 may eventually be diced into a plurality of dies.

After the forming the layered double hydroxide layer 108, various embodiments may include forming a further ALD layer 220 over (the layered double hydroxide layer 108.

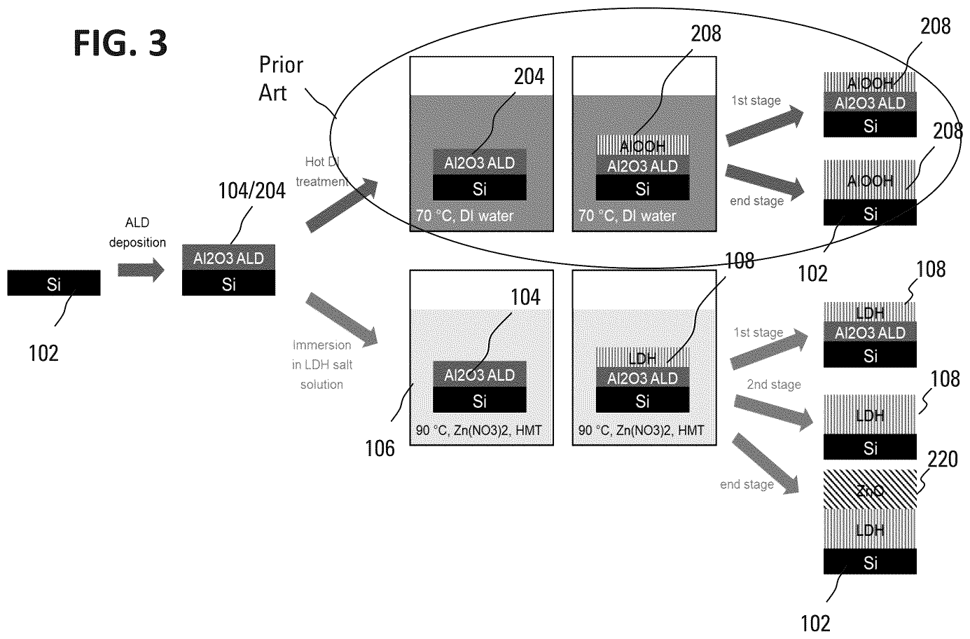

An exemplary embodiment of this is shown in FIG. 3, which schematically illustrates a comparison between a prior art method of forming a roughened surface on a substrate (in the shown example the chip structure 102 is a silicon substrate) in the top branch and a method in accordance with various embodiments in the bottom branch. The starting point for both methods is with an ALD aluminum oxide layer 104/204 provided on the chip structure 102. The double reference 104/204 is used here for the aluminum oxide layer 104/204, because, in the prior art and in this context, the forming an LDH layer 208 by dipping into hot water is known only for aluminum oxide 204, whereas, in accordance with a prior art, a general metal oxide layer 104 may be used, with aluminum oxide as just one exemplary embodiment.

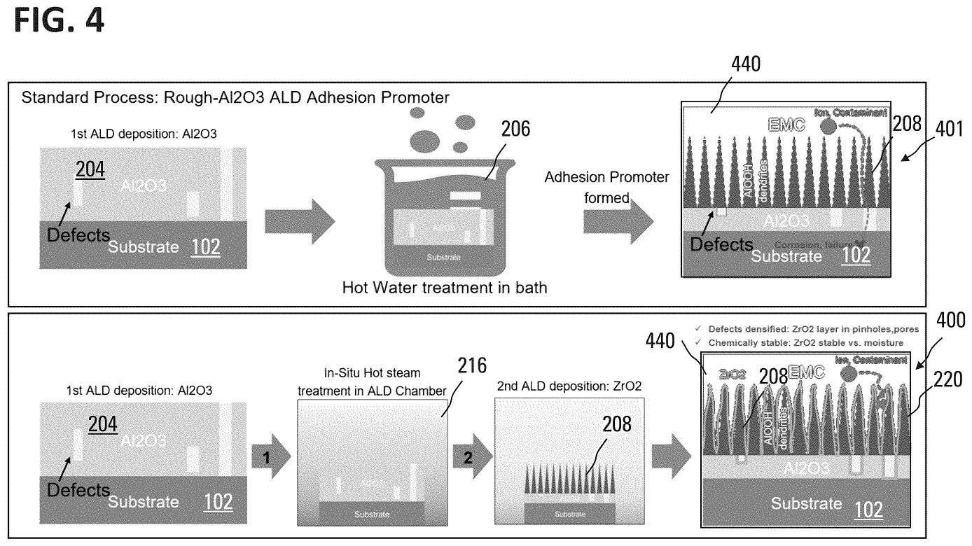

According to the prior art, which is also illustrated in FIG. 4 (top), the chip structure 102 with the aluminum oxide layer 204 is dipped into hot (e. g., deionized) water to be hydrothermally converted into a porous boehmite like AlOOH structure, with partial or complete conversion of the aluminum oxide layer 204.

In contrast to this, the chip structure 102 with the aluminum oxide layer 104 is, in various embodiments, dipped into a saline solution 106 to form the LDH layer 108, also here, with either partial or complete conversion of the aluminum oxide layer 104. The further ALD layer 220, in the exemplary embodiment a ZnO layer, may optionally be applied on top of (e. g., directly on) the LDH layer 108.

From the above description, it is evident that the process to form the LDH 108 is very similar to the formation of the AlOOH 208 in the standard process. In various embodiments, the hydrothermal treatment is changed to a salt solution treatment to form the LDH structure 108 instead of the AlOOH-dendrites 208 that are formed by pure DI water treatment.

The following table gives an overview over some possible process parameters:

| Parameter | Range / Possibilities | Preferred |
|---|---|---|
| ALD thickness | 5-50 nm | 25 nm |
| ALD materials | AlOx, ZrOx, HfOx, ZnO, | AlOx |
| | MgO, CaOx, FeOx | |
| Primary salt | Zn(NO₃)₂, Zn(SO₄), | Zn(NO₃)₂ |
| additive for LDH | Mg(SO₄), Ca(SO₄), | |
| formation | Ca(NO₃)₂, Fe(NO₃)₂, | |
| | Fe(NO₃)₃, Fe(SO₄), | |
| | Fe₂(SO₄)₃, Al(NO₃)₃, | |
| | Al₂(SO₄)₃ | |
| Secondary | Hexamethylentetramine, | Hexamethylentetramine |
| additive for LDH | NaOH, HNO3, Amines, | |
| formation | | |
| Tertiary additive | Silanes, Triazoles, BTA, | BTA, Silane, MoOx |
| (inhibitor, | MoOx, VxOy, MnOx, | |
| hydrophobic | Anti-tarnish, hydrophobic | |
| agents, . . . ) | agents | |
| Immersion | 50-100° C. | 70° C. (90° C.) |
| temperature | | |
| Immersion time | 1-20 min | 3 min |
| Conversion % of | 10-100% | 60-80% |
| ALD layer | | |
| LDH conversion | Hydrothermal, sol-gel, | Hydrothermal treatment |
| method | coprecipitation, | |
| | electrodeposition, | |
| | steaming coating | |

FIGS. 5, 6A and 6B illustrate some embodiments of devices in accordance with various embodiments, which may for example have been produced by the method described above and in context with e. g., FIG. 1.

FIG. 5 schematically illustrates a chip package 500 in accordance with various embodiments, FIG. 6A schematically illustrates a wafer- or chip structure 600 in accordance with various embodiments, and FIG. 6B schematically illustrates a chip package component 601 in accordance with various embodiments.

FIG. 5 illustrates an embodiment, in which, after wirebonding, a chip assembly including a chip structure/a chip 102, a leadframe 550, to which the chip 102 is attached by a solder, a passivation layer 554 (e. g., an imide) and bonding wires 556 bonded to the chip 102 were, as a unit, provided with the metal oxide layer 104 and then exposed to the saline solution 106 to form the LDH layer 108 covering and protecting the chip assembly from corrosion and/or from ions accumulating on the surface. This may lead to a reliability improvement and/or to an HTRB drift improvement.

The chip assembly was subsequently embedded in encapsulation material 440, for example an (epoxy) mold compound, more generally an organic matrix, and the LDH layer 108 provides improved adhesion between the chip assembly and the encapsulation material 440. This may be referred to as a package level application.

A benefit of aspects of various embodiments may be a uniform ALD layer 104 deposited on every surface, which is then conversed to a densified LDH structure 108 (due to volume expansion) which typically grows crystallites perpendicular to the chip structure 102, e. g., a substrate. These crystallites act by mechanical interlocking to the molding compound or imide or any other organic matrix to act as adhesion promoter. Also, the LDH crystal act as ion traps for foreign ions and contaminants. Both mechanisms are illustrated for example in FIGS. 5, 6A and 6B.

FIG. 6A illustrates an embodiment where the metal oxide layer 104 is applied at a wafer level (in other words, the chip structure 102 is a wafer including a plurality of chips). Instead of or in addition to an encapsulation material 440, a passivation layer 554, e. g., an imide or other (e. g., organic or inorganic) passivation layer may be applied directly onto the LDH layer 108 to interlock with it. Another LDH layer 108 may optionally be formed between the passivation layer 554 and the encapsulation material 440 (not shown).

As shown in FIG. 6B, the chip structure 102 may be a carrier or substrate, e. g., a leadframe, e. g., an aluminum leadframe, that is configured to become part of a chip package 500, but which, at the time of applying the LDH layer 108 may possibly not yet be provided with the chip 102. An aluminum leadframe 550 may have an advantage in that a native Al₂O₃ oxide that may form on the leadframe 550 may be suitable for conversion to the LDH layer 108 in the saline solution 106, but other leadframes, substrates or carriers may in other embodiments be provided with the LDH layer 108, for example after ALD deposition of a metal oxide layer 104. The advantages correspond to those described above for the package level and the wafer level applications.

One of the preferred embodiments of the method for package assembly and wafer level application is to deposit a uniform ALD layer 104 such as Al₂O₃ or ZnO (or other oxide), since the formation of the LDH structure 108 requires an oxide as substrate. After the ALD deposition is done, the substrate with the ALD layer is conversed to the LDH structure by hydrothermal treatment. An example for such a hydrothermal treatment is to put the ALD deposited sample into a salt solution of Zn(NO₃)₂ at 90° C. for 10 min to form ZnAl-LDH.

The thin ALD layer (~10-25 nm) is conversed to a thick layer having a thickness of about 1 μm with a dendritic structure similar to the Al₂O₃ ALD adhesion promoter. Such a thicker layer may exhibit better corrosion properties due to the higher thickness and densified structure at the bottom of the layer. Also, the ZnAl-LDH employs ion catching properties. Thus, combining corrosion protection and adhesion layer.

However, independently of native Al₂O₃ or thin ALD Al₂O₃, the main principle is the conversion of the thin Al₂O₃ layer 104 with a salt solution 106 to the desired LDH layer 108. This may for example be realized by a zinc- or magnesium salt solution, but other bivalent ions are also possible, such as Fe2+. Thus, any bivalent oxide can be conversed with a trivalent salt or vice versa, a trivalent oxide can be conversed with a bivalent oxide to form the layered double hydroxide. As the formation of LDH may require a bivalent and trivalent metal ion (typically Mg2+, Al3+, Fe2+/3+, Zn2+): [M (II)₁₋ₓM(III)ₓ(OH⁻)₂]^{x+} [(Xⁿ⁻)_{x/n}·yH₂O]^{x-} which is hydrolyzed during the process to form the double layer hydroxide structures where anions will be intercalated during the process. The intercalated ions then depend on the used salt solution and the specific procedure.

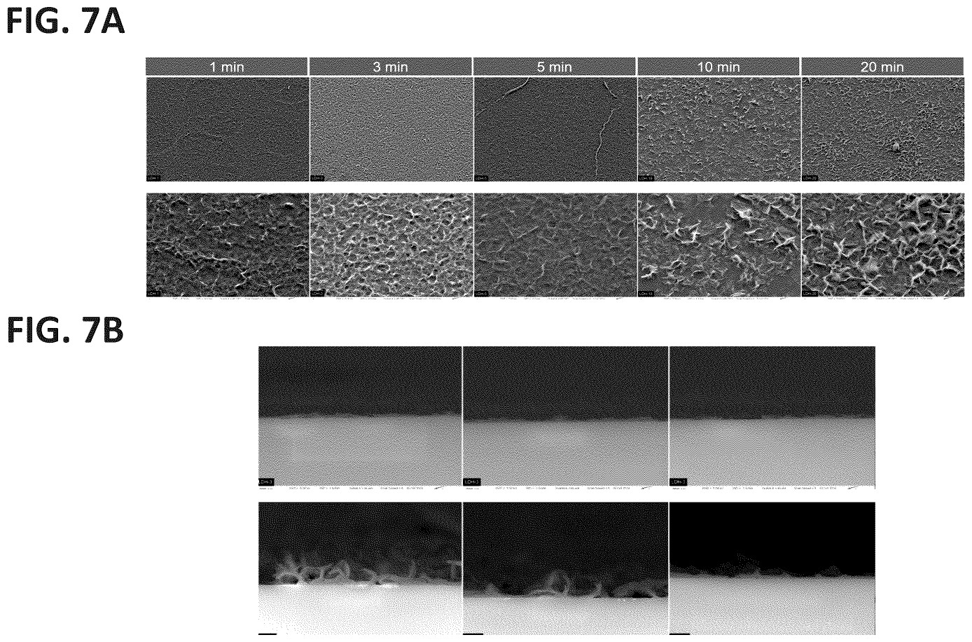

FIG. 7A shows scanning electron microscope (SEM) images of substrates 102 roughened with a layered double hydroxide (LDH) 108 in accordance with various embodiments, and FIG. 7B shows cross-sectional images of some of the substrates of FIG. 7A, both, FIGS. 7A and 7B showing a lower magnification in the top row and a higher magnification in the bottom row.

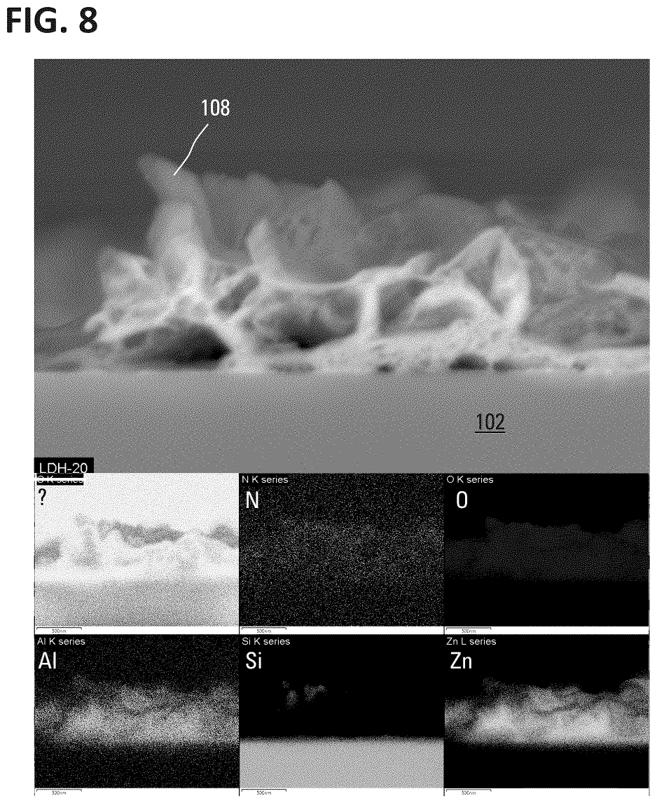

FIG. 8 shows a scanning electron microscope (SEM) image of a cross section of a silicon substrate 102 roughened with a layered double hydroxide (LDH) 108 in accordance with various embodiments (top) and scanning electron microscope (SEM) images combined with Energy Dispersive X-ray Spectroscopy (EDX) below.

For the experiments, Cu and Si pieces 102 with 25 nm Al₂O₃ ALD deposited layers 104 prior to the immersion in salt solution 106 were used.

The results of the experiments were positive in terms of conversion and dendrite formation. Thus, the LDH formation from ALD layers is feasible and the concept works.

The surfaces shown in FIG. 7A clearly show formation of a dendritic structure. Analysis with EDX (see FIG. 8) reveals the formation of ZnO and LDH crystallites that mainly include Zn, Al and O.

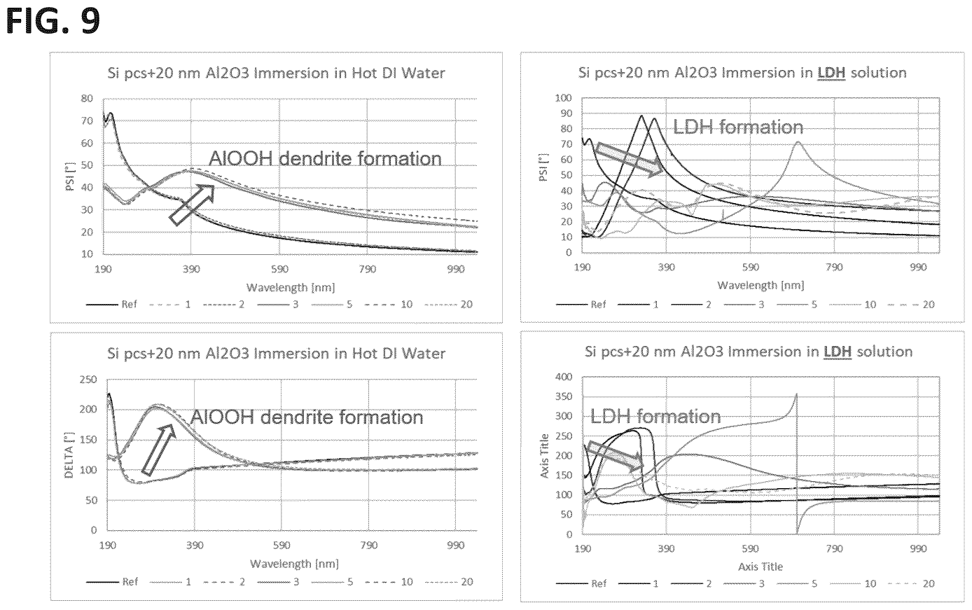

FIG. 9 shows a comparison of ellipsometry measurements on small Si-pieces after hydrothermal treatment in pure DI water (left, prior art) and 0.5 M Zn(NO₃)₂ solution (right, in accordance with various embodiments) at 90° C. for different times.

FIG. 9 illustrates how fast LDH formation sets in after immersion into the saline solution (at 90° C.), and how this compares to the prior art method of dipping in hot deionized water: a change in thickness and morphology does take place for Al₂O₃ ALD layer in Zn(NO₃)₂ solution after ~1-3 min immersion at 90° C. Also, slight white precipitate/discoloration can be observed on the Si test pieces. Rinsing with DI water and isopropanol does not wash away the discoloration.

The method in accordance with the prior art described above (dipping a chip structure 102 with an aluminum oxide layer into hot water) may be modified in at least two other ways for providing an adhesion promotion layer 108 in accordance with various embodiments.

FIG. 2 schematically illustrates those method of forming a chip package in accordance with various embodiments, and FIG. 4 compares schematical illustrations of a method of forming a chip package in accordance with various embodiments combining the two methods (bottom), and of a method of forming a chip package according to a prior art (top).

In various embodiments, rather than dipping into hot deionized water (illustrated for example in FIG. 4, top panel), the chip structure 102 having the aluminum oxide layer 204 arranged thereon (e. g., an ALD layer 204 and/or a native oxide layer 204) may according to various embodiments be exposed to hot water vapor/steam 216.

This is illustrated in an exemplary fashion in the right branch of FIG. 2 and in the bottom panel of FIG. 4.

Preferably, but optionally, the hot steam treatment may be performed in situ, in other words, in the processing chamber that may have been used for forming the ALD aluminum oxide layer 204.

In accordance with the other modification of the prior art process, the method of various embodiments may further provide an atomic layer deposition, for example of another oxide layer 220, on the converted aluminum oxide layer 208.

This is illustrated in the left panel of FIG. 2 and the bottom panel of FIG. 4.

FIG. 2 further illustrates that various combinations of those two modifications may be possible: in both, the water dipping and the hot steam treatment case, the aluminum oxide layer 204 may be completely or partially converted into the LDH layer 208, and the hot steam treated chip structure 102 may optionally be provided with the top ALD layer 220.

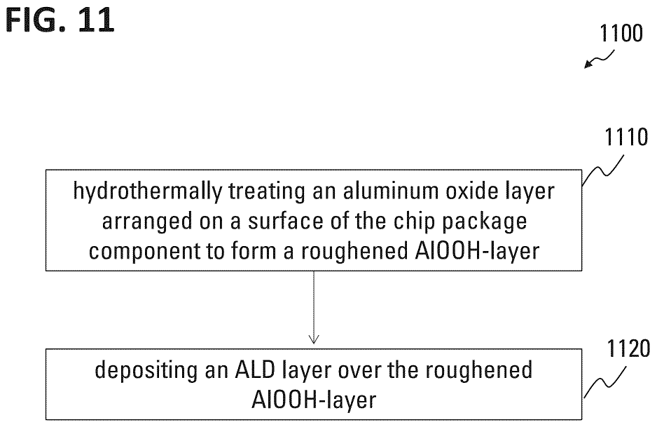

FIG. 11 shows a flow diagram 1100 of a method for manufacturing a chip package component in accordance with various embodiments.

The method includes hydrothermally treating an aluminum oxide layer arranged on a surface of the chip package component to form a roughened AlOOH-layer (1110), and depositing an ALD layer over the roughened AlOOH-layer (1120).

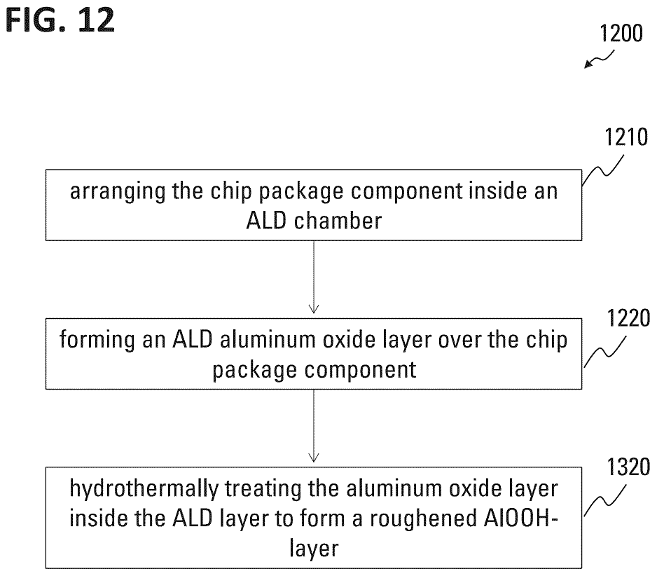

FIG. 12 shows a flow diagram 1200 of a method for manufacturing a chip package component in accordance with various embodiments.

The method includes arranging the chip package component inside an ALD chamber (1210), forming an ALD aluminum oxide layer over the chip package component (1220), and hydrothermally treating the aluminum oxide layer inside the ALD layer to form a roughened AlOOH-layer (1320).

In the following, various aspects of this disclosure will be illustrated:

Example 1 is a method for manufacturing a chip package. The method includes forming a metal oxide layer on a chip structure and applying a saline solution to the metal oxide layer to form a layered double hydroxide (LDH).

In Example 2, the subject matter of Example 1 may optionally further include forming an encapsulation layer on the layered double hydroxide.

In Example 3, the subject matter of Example 1 or 2 may optionally include that the metal oxide layer includes or essentially consists of at least one metal oxide of a group of metal oxides, the group consisting of: aluminum oxide, zinc oxide, hafnium oxide, manganese oxide, calcium oxide, and iron oxide.

In Example 4, the subject matter of any of Examples 1 to 3 may optionally include that the saline solution includes at least one salt of a group of salts, the group consisting of: Zn(NO₃)₂, Zn(SO₄), Mg(SO₄), Ca(SO₄), Ca(NO₃)₂, Fe(NO₃)₂, Fe(NO₃)₃, Fe(SO₄), Fe₂(SO₄)₃, Al(NO₃)₃, and Al₂(SO₄)₃.

In Example 5, the subject matter of any of Examples 1 to 4 may optionally include that the saline solution further includes at least one additive of a group of additives, the group including: hexamethylentetramine, NaOH, HNO3, and amines.

In Example 6, the subject matter of any of Examples 1 to 5 may optionally include that the saline solution further includes at least one further additive of a group of further additives, the group including: silanes, triazoles, benzotriazole (BTA), MoOx, VxOy, MnOx, anti-tarnish, and hydrophobic agents.

In Example 7, the subject matter of any of Examples 1 to 6 may optionally include that the applying a saline solution includes or consists of at least one of a group of techniques, the group consisting of: hydrothermal treatment, a sol-gel method, a coprecipitation method, a template method, a urea hydrolysis method, electrodeposition, spin coating, steaming coating, and anion exchange.

In Example 8, the subject matter of any of Examples 1 to 7 may optionally include that the forming the layered double hydroxide completely consumes the metal oxide layer.

In Example 9, the subject matter of any of Examples 1 to 8 may optionally include that the forming the layered double hydroxide consumes the metal oxide layer only partially, with a fraction of the thickness of the metal oxide layer remaining between the layered double hydroxide and the chip structure.

In Example 10, the subject matter of any of Examples 1 to 9 may optionally include that the chip structure is a wafer, the method further including: forming an imide layer over the layered double hydroxide.

In Example 11, the subject matter of Example 10 may optionally include that the layered double hydroxide, and optionally the imide layer, covers at least one side of the wafer or essentially covers at least one side of the wafer.

In Example 12, the subject matter of Example 10 or 11 may optionally include, after forming the imide layer, dicing the wafer into a plurality of dies.

In Example 13, the subject matter of any of Examples 1 to 12 may optionally further include, after the forming the layered double hydroxide, forming a further ALD layer over the layered double hydroxide.

Example 14 is a chip package. The chip package includes a chip structure, and a layered double hydroxide formed on the chip structure.

In Example 15, the subject matter of Example 14 may optionally further include an encapsulation layer on the layered double hydroxide.

In Example 16, the subject matter of Example 14 or 15 may optionally further include an ALD layer directly on the layered double hydroxide.

In Example 17, the subject matter of any of Examples 14 to 16 may optionally include that the layered double hydroxide includes at least one metal of a group of metals, the group consisting of: aluminum, zinc, hafnium, manganese, calcium, and iron titanium, boron, cadmium, and copper.

In Example 18, the subject matter of any of Examples 14 to 17 may optionally include that the layered double hydroxide has a dendritic and/or platelet structure.

In Example 19, the subject matter of any of Examples 14 to 18 may optionally include that the chip structure includes or consists of at least one of a group of chip structures, the group consisting of: a wafer, a reconstituted wafer, a chip assembly, and a leadframe.

In Example 20, the subject matter of any of Examples 14 to 19 may optionally further include a metal oxide layer that is a remnant of a thicker metal oxide layer from which the layered double hydroxide has been formed, the metal oxide layer being arranged between the layered double hydroxide and the chip structure.

In Example 21, the subject matter of any of Examples 14 to 20 may optionally include that the metal hydroxide layer conforms to the chip structure.

Example 22 is a wafer structure. The wafer structure includes a wafer including a plurality of dies before singulation, and a layered double hydroxide formed on the wafer.

In Example 23, the subject matter of Example 22 may optionally further include an imide layer on the layered double hydroxide.

In Example 24, the subject matter Example 22 or 23 may optionally include that the layered double hydroxide covers at least one side of the wafer or essentially covers at least one side of the wafer.

Example 25 is a method for processing a chip package component. The method includes hydrothermally treating an aluminum oxide layer arranged on a surface of the chip package component to form a roughened AlOOH-layer, and depositing an ALD layer over the roughened AlOOH-layer.

In Example 26, the subject matter Example 25 may optionally include that the aluminum oxide layer is a native aluminum oxide layer and/or a deposited aluminum oxide layer.

In Example 27, the subject matter of Example 25 or 26 may optionally include that the hydrothermally treating the aluminum oxide layer and the depositing an ALD layer are performed in the same processing chamber.

In Example 28, the subject matter of any of Examples 25 to 27 may optionally include that the ALD layer is an oxide layer, optionally a zirconium oxide layer or an aluminum oxide layer.

In Example 29, the subject matter of any of Examples 25 to 28 may optionally include that the hydrothermally treating the aluminum oxide layer includes exposing the aluminum oxide layer to hot water steam and/or dipping the chip package component into hot water.

Example 30 is a method for processing a chip package component. The method includes arranging the chip package component inside an ALD chamber, forming an ALD aluminum oxide layer over the chip package component, and hydrothermally treating the aluminum oxide layer inside the ALD layer to form a roughened AlOOH-layer.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for manufacturing a chip package, the method comprising:
forming a metal oxide layer on a chip structure; and
applying a saline solution to the metal oxide layer to form a layered double hydroxide (LDH).

2. The method of claim 1, further comprising:
forming an encapsulation layer on the layered double hydroxide.

3. The method of claim 1,
wherein the metal oxide layer comprises at least one metal oxide of a group of metal oxides, the group consisting of:
aluminum oxide;
zinc oxide;
hafnium oxide;
manganese oxide;
calcium oxide; and
iron oxide.

4. The method of claim 1,
wherein the saline solution comprises at least one salt of a group of salts, the group consisting of:

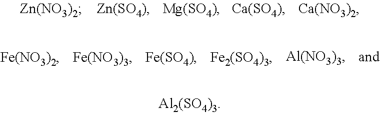

5. The method of claim 1,
wherein the saline solution further comprises at least one additive of a group of additives, the group comprising:
hexamethylentetramine;
NaOH;
HNO₃; and
amines.

6. The method of claim 1,
wherein the saline solution further comprises at least one further additive of a group of further additives, the group comprising:
silanes,
triazoles,
benzotriazole (BTA),
MoOx,
VxOy,
MnOx,
anti-tarnish; and
hydrophobic agents.

7. The method of claim 1,
wherein the applying a saline solution comprises at least one of a group of techniques, the group consisting of:
hydrothermal treatment;
a sol-gel method;
a coprecipitation method;
a template method;
a urea hydrolysis method;
electrodeposition;
spin coating;
steaming coating; and
anion exchange.

8. The method of claim 1,
wherein the forming the layered double hydroxide completely consumes the metal oxide layer.

9. The method of claim 1,
wherein the forming the layered double hydroxide consumes the metal oxide layer only partially, with a fraction of the thickness of the metal oxide layer remaining between the layered double hydroxide and the chip structure.

10. The method of claim 1,
wherein the chip structure is a wafer, the method further comprising: forming an imide layer over the layered double hydroxide.

11. The method of claim 10,
wherein the layered double hydroxide, and optionally the imide layer, covers at least one side of the wafer or essentially covers at least one side of the wafer.

12. The method of claim 10, further comprising:
after forming the imide layer, dicing the wafer into a plurality of dies.

13. The method of claim 1, further comprising:
after the forming the layered double hydroxide, forming a further ALD layer over the layered double hydroxide.

14. A chip package, comprising:
a chip structure; and
a layered double hydroxide formed on the chip structure.

15. The chip package of claim 14, further comprising:
an encapsulation layer on the layered double hydroxide.

16. The chip package of claim 14, further comprising:
an ALD layer directly on the layered double hydroxide.

17. The chip package of claim 14,
wherein the layered double hydroxide comprises at least one metal of a group of metals, the group consisting of:
aluminum;
zinc;
hafnium;
manganese;
calcium;
iron;
titanium;
boron;
cadmium; and
copper.

18. The chip package of claim 14,
wherein the layered double hydroxide has a dendritic and/or platelet structure.

19. The chip package of claim 14,
wherein the chip structure comprises at least one of a group of chip structures, the group consisting of:
a wafer;
a reconstituted wafer;
a chip assembly; and
a leadframe.

20. The chip package of claim 14, further comprising:
a metal oxide layer that is a remnant of a thicker metal oxide layer from which the layered double hydroxide has been formed, the metal oxide layer being arranged between the layered double hydroxide and the chip structure.

21. The chip package of claim 14,
wherein the metal hydroxide layer conforms to the chip structure.

22. A wafer structure, comprising:
a wafer comprising a plurality of dies before singulation; and
a layered double hydroxide formed on the wafer.

23. The wafer structure of claim 22, further comprising:
an imide layer on the layered double hydroxide.

24. The wafer structure of claim 22,
wherein the layered double hydroxide covers at least one side of the wafer or essentially covers at least one side of the wafer.

25. A method for processing a chip package component, the method comprising:
hydrothermally treating an aluminum oxide layer arranged on a surface of the chip package component to form a roughened AlOOH-layer; and
depositing an ALD layer over the roughened AlOOH-layer.

26. The method of claim 25,
wherein the aluminum oxide layer is a native aluminum oxide layer and/or a deposited aluminum oxide layer.

27. The method of claim 25,
wherein the hydrothermally treating the aluminum oxide layer and the depositing an ALD layer are performed in the same processing chamber.

28. The method of claim 25,
wherein the ALD layer is an oxide layer, optionally a zirconium oxide layer or an aluminum oxide layer.

29. The method of claim 25,
wherein the hydrothermally treating the aluminum oxide layer comprises exposing the aluminum oxide layer to hot water steam and/or dipping the chip package component into hot water.

30. A method for processing a chip package component is provided, the method comprising:
arranging the chip package component inside an ALD chamber;
forming an ALD aluminum oxide layer over the chip package component; and
hydrothermally treating the aluminum oxide layer inside the ALD layer to form a roughened AlOOH-layer.
